(19) United States
(12) Patent Application Publication
(10) Pub. No.: US 2020/0389160 A1
(43) Pub. Date: Dec. 10, 2020

(54) STRONGARM LATCH COMPARATOR AND METHOD

(71) Applicant: KING ABDULLAH UNIVERSITY OF SCIENCE AND TECHNOLOGY, Thuwal (SA)

(72) Inventors: Abdullah Saud ALMANSOURI, Thuwal (SA); Abdullah Turki ALTURKI, Thuwal (SA); Talal AL-ATTAR, Thuwal (SA)

(21) Appl. No.: 16/492,341

(22) PCT Filed: Jan. 17, 2018
(86) PCT No.: PCT/IB2018/050290

§ 371 Date: Sep. 9, 2019

Related U.S. Application Data
(60) Provisional application No. 62/500,136, filed on May 2, 2017.

(51) Int. Cl. H03K 5/24; H03K 17/687

(52) U.S. Cl. CPC H03K 5/2481; H03K 17/6872; H03K 5/249

(57) ABSTRACT

A StrongARM latch comparator (500) includes first and second p-type metal-oxide-semiconductor, PMOS, cross-coupled transistors (T1, T2); third and fourth n-type metal-oxide-semiconductor, NMOS, cross-coupled transistors (T3, T4), wherein the first PMOS cross-coupled transistor (T1) has a gate electrically coupled to a gate of the third NMOS cross-coupled transistor (T3) and the second PMOS cross-coupled transistor (T2) has a gate electrically coupled to a gate of the fourth NMOS cross-coupled transistor (T4); and fifth and sixth input transistors (T5, T6). The fifth input transistor (T5) is electrically connected between the first PMOS cross-coupled transistor (T1) and the third NMOS cross-coupled transistor (T3), and the sixth input transistor (T6) is electrically connected between the second PMOS cross-coupled transistor (T2) and the fourth NMOS cross-coupled transistor (T4).

### CROSS REFERENCE TO RELATED APPLICATIONS

This application claims priority and benefit from U.S. Provisional Patent Application No. 62/500,136, filed on May 2, 2017, for “Improved StrongARM Latch Comparator Architecture and Performance in CMOS Technology,” the content of which is incorporated in its entirety herein by reference.

### BACKGROUND

### Technical Field

Embodiments of the subject matter disclosed herein generally relate to a StrongARM latch comparator architecture, and more specifically, to methods and systems for improving energy consumption, speed and/or clock feedthrough of a StrongARM latch comparator architecture.

### Discussion of the Background

A StrongARM latch comparator is a well-known topology. It has some features that made it unique, such as 1) it does not consume static power, 2) it produces rail-to-rail output, 3) it has small input referred offset, and 4) it has high input impedance, as discussed in references [1] and [2]. These favorable features paved the way for the latch comparator to be widely used as a sense amplifier, a comparator or a robust latch [1]. For these reasons, it is common to find the StrongARM latch in analog-to-digital converters (ADCs) [2], Flip-Flops circuits [3], sense amplifier, etc.

The original StrongARM latch was first introduced in 1993 (see [4]) and its configuration is shown in FIG. 1. StrongARM latch 100 includes 9 transistors, two charging transistors CT1 and CT2, four cross-coupled transistors T1 to T4, two input transistors T5 and T6, and one tail current transistor T7. A CLK signal (clock signal) is applied to the gates of the charging transistors and the tail current transistor, a common mode voltage V_{CM} is applied to both input transistors. One of the input transistors has a small differential voltage V_{diff} in addition to the common mode voltage V_{CM}. The cross-coupled transistors have their gates interconnected in pairs as illustrated in FIG. 1. It is noted that for this configuration, the input transistors T5 and T6 are electrically connected between the cross-coupled transistors and the tail current transistor.

The original architecture of the StrongARM configuration 100 has been improved over time to improve the robustness of the circuit, as discussed in [5] and [6]. In return, the size, speed and efficiency of the latch were compromised. FIG. 2 shows a schematic of the improved conventional StrongARM latch 200 proposed by [5]. This latch configuration includes 11 transistors: charging transistors (CT1, CT2, CT3, and CT4), cross-coupled transistors (T1, T2, T3 and T4), input transistors (T5 and T6) and one tail current transistor (T7) with the input transistors T5 and T6 also electrically connected between the cross-coupled transistors and the tail current transistor.

In general, the operation of an ideal latch passes through three phases: Reset, Amplification, and Regeneration, as illustrated in FIG. 3. Reset phase 302 starts when the CLK signal 304 goes Low (note the low value of the signal on the Y axis, which is the voltage amplitude), hence, charging the internal capacitors at the nodes A, A′, B and B′ to the drain voltage V_{DD} through the charging transistors. The amplification phase 306 starts when the CLK signal goes High, turning all charging transistors OFF and allowing the current in the circuit to discharge through the tail current transistor T7. Transistors T5 and T6 in FIG. 2 are biased by the constant voltage V_{CM}. Thus, these transistors are always ON. The voltage V_{diff} is added to V_{CM} in one input, e.g., transistor T5, causing a slight difference between the current flowing through these two transistors.

As a consequence, the capacitors at nodes B and B′ (the equivalent capacitance of the circuit seen at nodes B and B′) are discharged at slightly different speeds, and therefore, the voltages at these nodes drop at different rates. Transistors T3 and T4 turn ON when the voltages at nodes B and B′ reach the value V_{DD}−Vₜₕₙ, where Vₜₕₙ is the threshold voltage to turn on an NMOS transistor. After that, the voltages at nodes A and A′ start to drop at different rates, as illustrated by curves 320 and 330, respectively, in FIG. 3.

The regeneration phase 308 starts when the voltage at either A or A′ drops to V_{DD}−Vₜₕₚ turning either transistor T1 or T2 ON, and the other transistor remains OFF due to the cross-coupled configuration. As a result, the final voltage 320 reaches V_{DD} in one node (A or A′) and the final voltage 330 reaches zero volts for the other node (A′ or A), depending on the polarity of V_{diff}. The output from nodes A and A′ is taken to fed into inverters [1].

One of the limitations in this topology is the clock feedthrough problem. The voltages at A and A′ follow the clock for a short period, resulting in a first spike that is larger than V_{DD} when the clock goes to High (see spike in FIG. 6, at time of about 1 ps), and another spike, less than 0 volts (shown in FIG. 6 at about a time of 326 ps) when the clock goes Low. These spikes increase the period of both the amplification and reset phases, hence, increasing the overall delay of the circuit, which is undesirable.

The clock feedthrough problem is due to the gate-source (or gate-drain) coupling, through the internal capacitance. There are many well-known techniques to reduce the clock feedthrough problems. One such known solution connects additional capacitors/transistors at the gate of the charging transistors (see [7] and [8]), or replace the charging transistors with transmission gates (see [9]). However, by adding any transistor (or capacitor), the total capacitance in the circuit is increased, and hence, the speed of the latch is decreased, which is not desirable.

With the increasing interest in wearable electronics, Internet-of-Things (loT) and low power applications, the need for small, fast and power-efficient electronics is always present. Thus, there is a need for an improved design for the StrongARM latch that has a smaller area, faster performance and better power efficiency.

### SUMMARY

According to another embodiment, there is a StrongARM latch comparator that includes first and second p-type metal-oxide-semiconductor, PMOS, cross-coupled transistors; third and fourth n-type metal-oxide-semiconductor, NMOS, cross-coupled transistors, wherein the first PMOS cross-coupled transistor has a gate electrically coupled to a gate of the third NMOS cross-coupled transistor and the second PMOS cross-coupled transistor has a gate electrically coupled to a gate of the fourth NMOS cross-coupled transistor; and fifth and sixth input transistors. The fifth input transistor is electrically connected between the first PMOS cross-coupled transistor and the third NMOS cross-coupled transistor, and the sixth input transistor is electrically connected between the second PMOS cross-coupled transistor and the fourth NMOS cross-coupled transistor.

According to another embodiment, there is a method for driving a StrongARM latch comparator. The method includes applying a voltage V_{DD} to the sources of the first and second PMOS cross-coupled transistors; applying a ground voltage V₀ to a tail current transistor, wherein third and fourth NMOS cross-coupled transistors are connected to the tail current transistor, and wherein the first PMOS cross-coupled transistor has a gate electrically coupled to a gate of the third NMOS cross-coupled transistor and the second PMOS cross-coupled transistor has a gate electrically coupled to a gate of the fourth NMOS cross-coupled transistor; and applying a common mode voltage to a fifth input transistor and applying the common mode voltage and a small differential voltage to a sixth input transistor. The fifth input transistor is electrically connected between the first PMOS cross-coupled transistor and the third NMOS cross-coupled transistor, and the sixth input transistor is electrically connected between the second PMOS cross-coupled transistor and the fourth NMOS cross-coupled transistor.

According to still another embodiment, there is a circuit including first to fourth cross-coupled transistors, wherein the first cross-coupled transistor has a gate electrically coupled to a gate of the third cross-coupled transistor and the second cross-coupled transistor has a gate electrically coupled to a gate of the fourth cross-coupled transistor; and fifth and sixth input transistors. The fifth input transistor is directly, electrically, connected to the first cross-coupled transistor and to the third cross-coupled transistor and the sixth input transistor is directly, electrically, connected to the second cross-coupled transistor and the fourth cross-coupled transistor.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 illustrates a conventional StrongARM architecture;

FIG. 2 illustrates an improved conventional StrongARM architecture;

FIG. 3 illustrates the various phases through which a StrongARM circuit goes through;

FIG. 4 illustrates the voltages of a StrongARM circuit as the size of its transistors is increased;

FIG. 5 illustrates a novel StrongARM configuration;

FIG. 6 illustrates in a comparative manner the voltages of a novel StrongARM configuration relative to a conventional StrongARM configuration;

FIG. 7 illustrates a normalized energy delay product for novel and traditional StrongARM configurations for 90 nm CMOS technology;

FIG. 8 illustrates various characteristics for the novel and traditional StrongARM configurations for 90 nm CMOS technology;

FIG. 9 illustrates a variation of the minimal differential voltage with the common mode voltage for the novel and traditional StrongARM configurations;

FIG. 10 illustrates a normalized energy delay product for novel and traditional StrongARM configurations for 32 nm CMOS technology;

FIG. 11 illustrates various characteristics for the novel and traditional StrongARM configurations for 32 nm CMOS technology; and

FIG. 12 is a flowchart of a method for driving a novel StrongARM configuration.

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

In the following, an analysis of the voltage behavior of the traditional StrongARM latch comparator at each phase is presented. The voltage behavior can be modeled as charging or discharging capacitors. In the Reset phase, all the capacitors are recharged to V_{DD}. In the Amplification phase, the capacitors at nodes B and B′ followed by the capacitors at nodes A and A′ are partially discharged. In the Regeneration phase, the capacitors at nodes A and B (or A′ and B′) are recharged to V_{DD}, and the other two capacitors are fully discharged. The time needed for charging and discharging these capacitors determines the speed of this circuit.

The charging or discharging speed can be modeled by combining equations (1) and (2). Equation (1) describes the current behavior in a capacitor, which current is proportional with the change Δν in voltage over the time interval Δt, and equation (2) is the first order estimation for an RC circuit:

$$\begin{matrix}i = C \frac{Δ v}{Δ t} \to Δ v = \frac{i Δ t}{C} , and & ( 1 ) \\ Δ v = {V}_{DD} [ 1 - {e}^{\frac{- Δ t}{τ}} ] . & ( 2 )\end{matrix}$$

By combining equations (1) and (2), the following equation is obtained:

$$τ = - \frac{Δ t}{ln ( 1 - \frac{I \cdot Δ t}{C \cdot {V}_{DD}} )} . \qquad ( 3 )$$

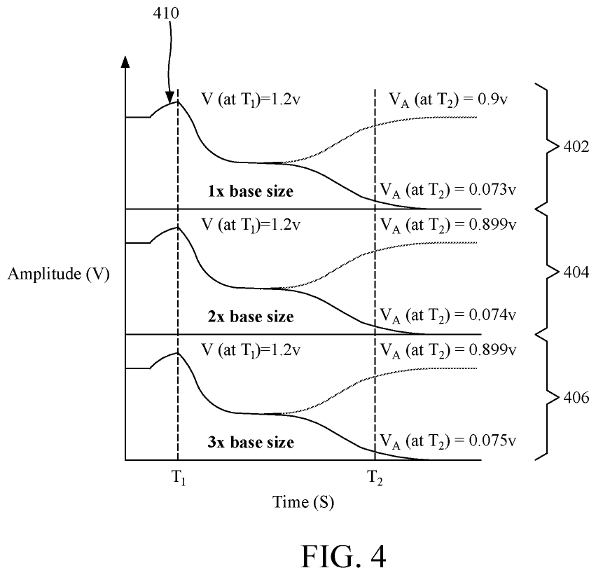

Equation (3) describes the relation between the current I, internal capacitance C and the total delay τ in a given phase. The speed of the circuit is proportional to the current I and inversely related to the internal capacitance C. The current can be improved in the circuit by using larger transistors (i.e., increasing the width of the transistor). However, this approach will also increase the internal capacitance in the circuit, hence, the total delay will remain the same. FIG. 4 illustrates that the sizing of the transistors for the whole circuit is scaled up by changing the width of the transistors (1× for case 402, 2× for case 404, and 3× for case 406, relative to the base size), and the voltage results are compared. All the cases provided a much similar performance in terms of speed, as anticipated by equation (3).

Thus, by simply increasing the size of the components of a traditional StrongARM configuration would not achieve the desired increased in performance, better power efficiency and/or using a smaller area, as desired for the wearable electronics, loT applications and low power applications.

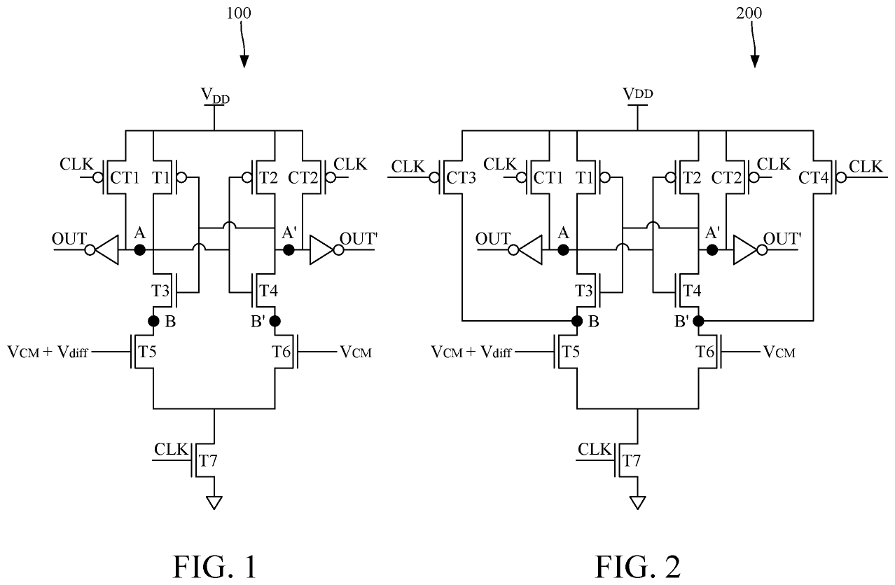

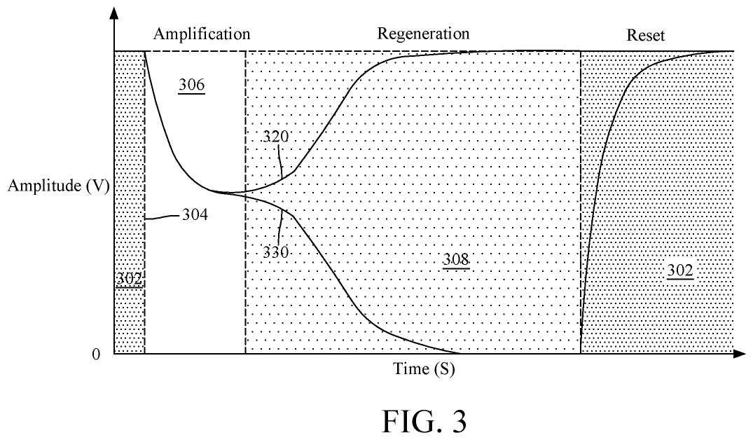

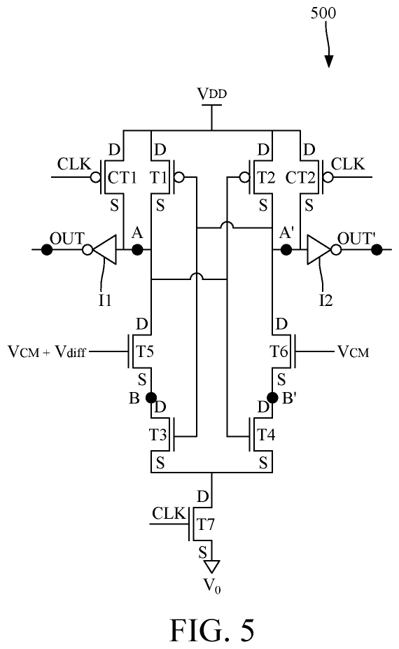

Therefore, according to an embodiment illustrated in FIG. 5, a novel StrongARM configuration is proposed, which includes 9 transistors. One advantage of this design over those illustrated in FIGS. 1 and 2 is the reduction of the total internal capacitance in the circuit without compromising the current. This advantage is achieved by placing/locating the input transistors in the middle, between the cross-coupled transistors. Because the input transistors are always ON, the need for the cross-coupled transistors CT3 and CT4 is eliminated and nodes B and B′ are recharged through the input transistors T5 and T6. As a consequence, the speed and efficiency of the latch are improved, while the clock feedthrough problem is reduced.

This embodiment is now discussed in more detail with regard to FIG. 5. The StrongARM latch comparator 500 includes 9 transistors placed differently than the transistors shown in the configurations illustrated in FIGS. 1 and 2. In this regard, while the input transistors T5 and T6 in the traditional configurations illustrated in FIGS. 1 and 2 are “electrically located” (i.e., electrically connected) between (1) the cross-coupled transistors T3 and T4 and (2) the tail current transistor T7, the input transistors T5 and T6 in the configuration illustrated in FIG. 5 are electrically located between the cross-coupled transistors T1 and T3 and T2 and T4, respectively. Note that tail current transistor T7 is connected to ground, i.e., a ground voltage V₀ is applied to one terminal (e.g., source).

This new configuration has the advantage of reducing the total internal capacitance in the circuit without compromising the current. Because the input transistors are always ON, the need for the charging transistors CT3 and CT4 in the configuration of FIG. 2 is eliminated and nodes B and B′ are recharged through the input transistors T5 and T6. As a consequence, the speed and efficiency of the latch 500 are improved, while the clock feedthrough problem is reduced.

FIG. 5 also shows two inverters I1 and I2 connected to nodes A and A′ respectively. Transistors T1 and T2 and CT1 and CT2 are PMOS (p-type metal-oxide-semiconductor) transistors and the remaining of the transistors are NMOS (n-type metal-oxide-semiconductor) transistors. Each of the two inverters I1 and I2 has a corresponding output node, OUT and OUT′. While the input of the latch comparator 500 is applied to the gates of transistors T5 and T6, the output is collected from inverters I1 and I2.

The latch comparator 500 in FIG. 5 indicates the drain and source of each transistor with symbols D and S, respectively.

The performance of the new design illustrated in FIG. 5 is now discussed. In this regard, it is noted that the results presented herein for the StrongARM latch comparator 500 use either 90 nm or 32 nm CMOS technology. The “CMOS” refers to both a particular style of digital circuitry design and the family of processes used to implement that circuitry on integrated circuits (chips). However, it is expected that the results next discussed are also applicable to other size CMOS transistors.

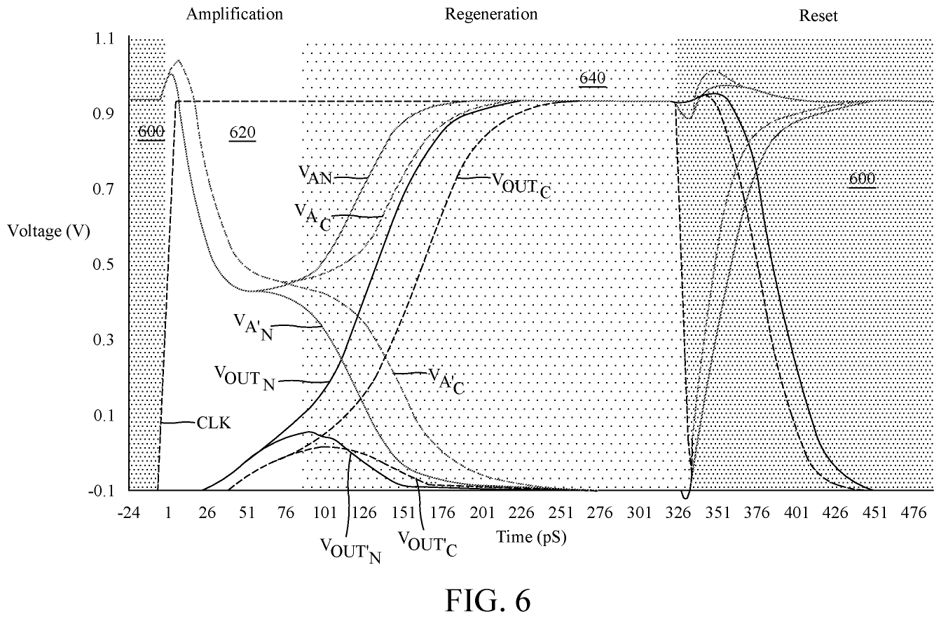

FIG. 6 shows the voltages for the various phases of a conventional latch comparator and the novel configuration illustrated in FIG. 5. The voltages for the conventional latch comparator have a subindex “c” while the voltages for the novel configuration of FIG. 5 have a subindex “n”. The voltages in FIG. 6 have been simulated for 90 nm CMOS technology. Three phases are illustrated in FIG. 6, the Reset 600, Amplification 620, and Regeneration 640. The small differential voltage V_{diff} applied to the inputs is 1 mV.

The CLK signal is shown being zero for the Reset phase 600 and one for the Amplification phase 620 and the Regeneration phase 640. The output voltage Voutₙ at node OUT and the output voltage Vout′ₙ at node OUT′ are shown in contrast to the Vout_{c} and Vout′_{c} of the conventional latch comparator. The voltages VAₙ and VA′ₙ at nodes A and A′ of the novel configuration of FIG. 5 are also plotted in contrast to the VA_{C} and VA′_{c} of the conventional configuration. All these voltages are plotted in FIG. 6 versus the time expressed in picoseconds.

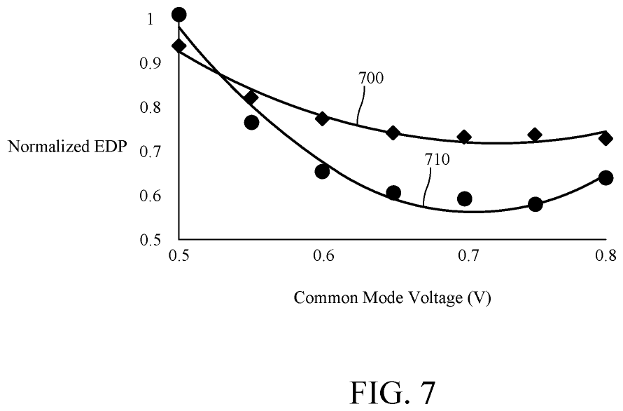

The new configuration latch comparator exhibits a peak of 21% efficiency improvement, 12% speed improvement and an average of 40% reduction in the clock feedthrough problem. The common mode voltage V_{CM} has a significant impact on the performance of the latches. In this regard, FIG. 7 shows the Energy Delay Product (EDP) (curve 700 for the conventional latch comparator and curve 710 for the configuration shown in FIG. 5) plotted versus the common mode voltage V_{CM} when V_{diff} is fixed at 1 mV. In general, the EDP performance for the proposed latch 500 is better compared to the conventional latch. The optimum performance is achieved when V_{CM} equal to 0.7V and 0.71V for the conventional and the proposed latches, respectively.

The figure also shows that the EDP performance for the new design 500 degrades when V_{CM} is lowered. The performance for both latches at low V_{CM} are controlled by the active transistors in the Amplification phase. The active transistors are T5, T6 and T7 for the conventional design of FIG. 1 and T3, T4, T5, T6 and T7 for the proposed design. From equation (3), it follows that the speed of the latch is proportional to the current, i.e., Speed∝I. The speed of the circuit is improved when all the active transistors are in saturation, and the worst case is achieved when any transistor is operating in the linear region, i.e., Iₛₐₜᵤᵣₐₜᵢₒₙ>Iₗᵢₙₑₐᵣ.

For the new latch comparator, the voltages at nodes B and B′ are related to V_{CM} by the equation (V_{b}−V_{B or B′}>V_{thn,T5 or T6}) to insure that the transistor is operating. Voltage Vₜₕₙ is the threshold voltage to turn on transistor T5 or T6. In other words, the voltages at nodes B and B′ are reduced when V_{CM} is lowered. By lowering the voltages at nodes B and B′, transistors T3 and T4 are forced to operate in the liner region, following the condition of operation (V_{DS}<V_{GS}−Vₜₕₙ), where V_{DS} is the drain-to-source voltage and V_{GS} is the gate-to-source voltage. As a result, the total current passing through the latch is reduced, and thus, its speed is also reduced. The conventional design, however, is less likely to suffer from this problem, because the input transistors (T5 and T6) are directly connected to T7. Following the same analogy, as V_{CM} increases to high values (higher than the optimum), T5 and T6 enter the linear region. As a consequence, the EDP performance is also worsened.

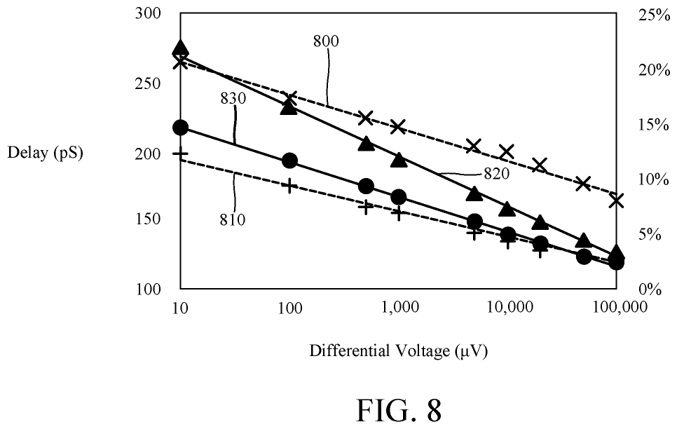

FIG. 8 shows the speed 800 and the efficiency 810 performance of both designs using their optimum V_{CM} and varying V_{diff} from 10 μV to 100 mV. The simulation shows an improved performance for the latch comparator 500, with improvement level inversely related to the differential voltage. For example, 21%, 14% and 8% speed improvement and 12%, 7% and 3% efficiency improvement are obtained when the differential voltage is 10 μV, 1 mV and 100 mV, respectively. FIG. 8 also shows the delay 820 for the conventional latch and the delay 830 for the new latch 500.

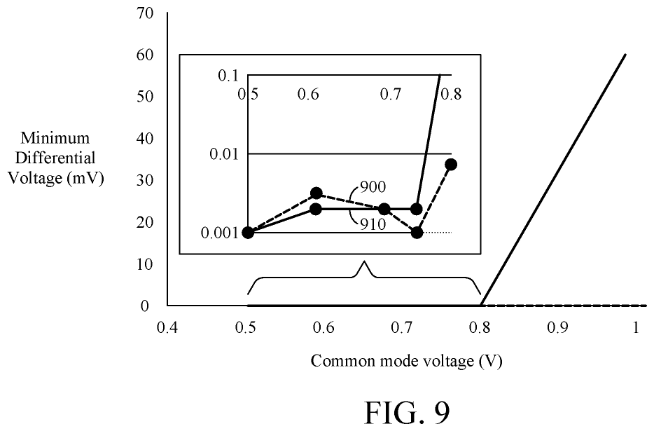

FIG. 9 shows the sensitivity 900 for the conventional latch and sensitivity 910 for the new latch 500. The minimum V_{diff} for the conventional design is in the range of micro-volts while the minimum V_{diff} for the new latch 500 is 2 μV when V_{CM}≤0.77V. The minimum V_{diff} is linearly related to the V_{CM} for V_{CM}>0.8.

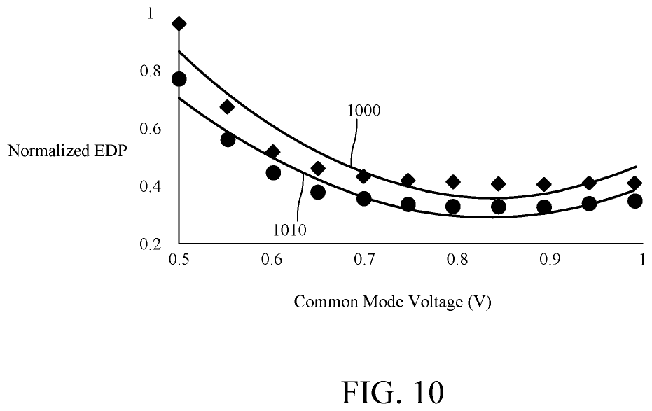

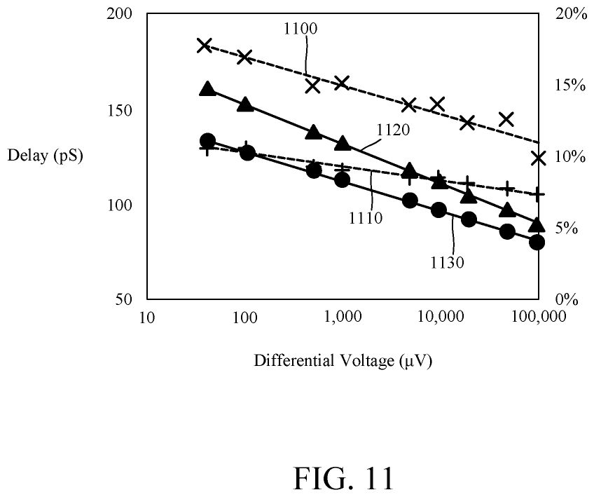

The performances illustrated in FIGS. 6-9 were estimated for 90 nm technology. The same performances for both latches are also simulated in the 32 nm technology. The optimum sizing is achieved by using the minimum possible size as the base size, and then ratio all the transistors to the base in a way that insures a smooth current flow. From FIG. 10, it can be seen that the optimum common mode voltage is around 0.84V for both designs. FIG. 10 illustrates the EDP 1000 for the conventional latch and the EDP 1010 for the latch 500. FIG. 11 shows performance comparisons for the latch 500 and conventional design in terms of speed 1100 and efficiency 1110. FIG. 11 also shows the delay 1120 for the conventional latch and the delay 1130 for the latch 500.

The proposed architecture 500 reduces the power consumption by a maximum of 21%, increases the speed by a maximum of 12% and reduces the clock feedthrough by an average of 40%. By testing the new architecture in 90 nm and 32 nm CMOS technologies, the proposed latch is able to deliver superior performance compared to the conventional ones.

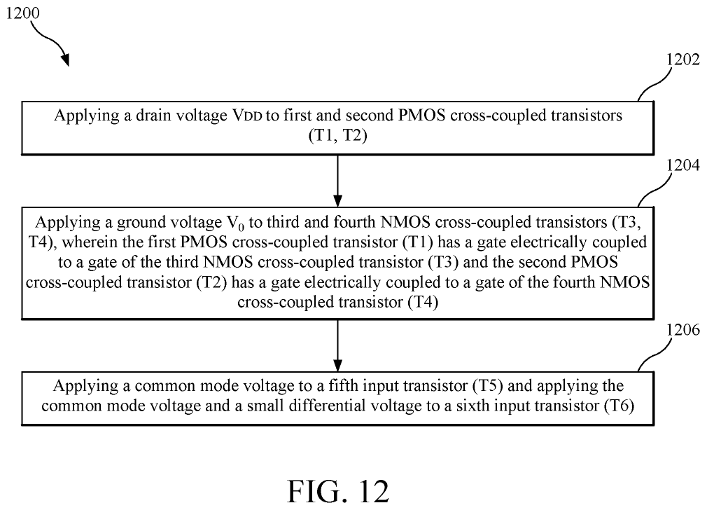

A method 1200 for driving a StrongARM latch comparator is now discussed with regard to FIG. 12. The method includes a step 1202 of applying a drain voltage V_{DD} to first and second PMOS cross-coupled transistors (T1, T2), a step 1204 of applying a ground voltage V₀ to third and fourth NMOS cross-coupled transistors (T3, T4), wherein the first PMOS cross-coupled transistor (T1) has a gate electrically coupled to a gate of the third NMOS cross-coupled transistor (T3) and the second PMOS cross-coupled transistor (T2) has a gate electrically coupled to a gate of the fourth NMOS cross-coupled transistor (T4); and a step 1206 of applying a common mode voltage to a fifth input transistor (T5) and applying the common mode voltage and a small differential voltage to a sixth input transistor (T6). The fifth input transistor (T5) is electrically connected between the first PMOS cross-coupled transistor (T1) and the third NMOS cross-coupled transistor (T3) and the sixth input transistor (T6) is electrically connected between the second PMOS cross-coupled transistor (T2) and the fourth NMOS cross-coupled transistor (T4).

In one application, a first charging transistor (CT1) is connected in parallel to the first cross-coupled transistor (T1) and a second charging transistor (CT2) is connected in parallel to the second cross-coupled transistor (T2).

The method may also include a step of applying a ground voltage to a tail current transistor (T7), which is connected to the third and fourth cross-coupled transistors (T3, T4), outputting a first output voltage VAₙ from a first inverter (I1) connected to a first node A; and outputting a second output voltage VA′ₙ from a second inverter (I2) connected to a second node A′. The method further may include a step of applying a drain voltage V_{DD} to a drain of the first cross-coupled transistor (T1), a drain of the first charging transistor (CT1), a drain of the second cross-coupled transistor (T2), and a drain of the second charging transistor (CT2). In one application, a source of the first cross-coupled transistor (T1) and a drain of the fifth input transistor (T5) are electrically connected to the first node A, and a source of the second cross-coupled transistor (T2) and a drain of the sixth input transistor (T6) are electrically connected to the second node A′. In another application, a source of the fifth input transistor (T5) is electrically connected to a drain of the third cross-coupled transistor (T3) and a source of the sixth input transistor (T6) is electrically connected to a drain of the fourth cross-coupled transistor (T4). In still another application, a source of the third cross-coupled transistor (T3) and a source of fourth cross-coupled transistor (T4) are directly connected to a drain of the tail current transistor (T7), and a source of the tail current transistor (T7) is connected to the ground.

The method further may include a step of applying a clock signal to a gate of the first charging transistor (CT1), a gate of the second charging transistor (CT2) and a gate of the tail current transistor (T7).

The disclosed embodiments provide a StrongARM configuration and method having better characteristics than the conventional architectures. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

[1] B. Razavi, “The StrongARM Latch [A Circuit for All Seasons],” IEEE Solid-State Circuits Magazine, vol. 7, pp. 12-17, 2015.

[2] S. Babayan-Mashhadi and R. Lotfi, “Analysis and Design of a Low-Voltage Low-Power Double-Tail Comparator,” Ieee Transactions on Very Large Scale Integration (Vlsi) Systems, vol. 22, pp. 343-352, February 2014.

[3] A. Abidi and H. Xu, “Understanding the Regenerative Comparator Circuit,” 2014 Ieee Proceedings of the Custom Integrated Circuits Conference (Cicc), 2014.

[4] T. Kobayashi, K. Nogami, T. Shirotori, and Y. Fujimoto, “A Current-Controlled Latch Sense Amplifier and a Static Power-Saving Input Buffer for Low-Power Architecture,” Ieee Journal of Solid-State Circuits, vol. 28, pp. 523-527, April 1993.

[5] Y.-T. Wang and B. Razavi, “An 8-Bit 150-MHz CMOS A/D Converter,” IEEE Journal of Solid-State Circuits, vol. 35, pp. 308-317, 2000.

[6] J. Montanaro, R. T. Witek, K. Anne, A. J. Black, E. M. Cooper, D. W. Dobberpuhl, et al., “A 160-MHz, 32-b, 0.5-W CMOS RISC microprocessor,” Ieee Journal of Solid-State Circuits, vol. 31, pp. 1703-1714, November 1996.

[7] H. K. Yang and E. I. Elmasry, “Clock Feedthrough Analysis and Cancellation in Current Sample Hold Circuits,” Iee Proceedings—Circuits Devices and Systems, vol. 141, pp. 510-516, December 1994.

[8] C. Eichenberger and W. Guggenbuhl, “Dummy Transistor Compensation of Analog Mos Switches,” Ieee Journal of Solid-State Circuits, vol. 24, pp. 1143-1146, August 1989.

[9] W. Z. Xu and E. G. Friedman, “Clock feedthrough in CMOS analog transmission gate switches,” 15th Annual Ieee International Asic/Soc Conference, Proceedings, pp. 181-185, 2002.

1. A StrongARM latch comparator comprising:
first and second p-type metal-oxide-semiconductor, PMOS, cross-coupled transistors (T1, T2);
third and fourth n-type metal-oxide-semiconductor, NMOS, cross-coupled transistors (T3, T4), wherein the first PMOS cross-coupled transistor (T1) has a gate electrically coupled to a gate of the third NMOS cross-coupled transistor (T3) and the second PMOS cross-coupled transistor (T2) has a gate electrically coupled to a gate of the fourth NMOS cross-coupled transistor (T4); and
fifth and sixth input transistors (T5, T6),
wherein the fifth input transistor (T5) is electrically connected between the first PMOS cross-coupled transistor (T1) and the third NMOS cross-coupled transistor (T3), and the sixth input transistor (T6) is electrically connected between the second PMOS cross-coupled transistor (T2) and the fourth NMOS cross-coupled transistor (T4).

2. The latch comparator of claim 1, further comprising:
a first charging transistor (CT1) connected to the first cross-coupled transistor (T1) so that their sources are connected to each other and their drains are connected to each other; and
a second charging transistor (CT2) connected to the second cross-coupled transistor (T2) so that their sources are connected to each other and their drains are connected to each other.

3. The latch comparator of claim 2, further comprising:
a tail current transistor (T7) connected to the third and fourth cross-coupled transistors (T3, T4).

4. The latch comparator of claim 3, further comprising:
a first inverter (I1) connected to a first node A; and
a second inverter (I2) connected to a second node A′.

5. The latch comparator of claim 4, wherein a source of the first cross-coupled transistor (T1), a source of the first charging transistor (CT1), a source of the second cross-coupled transistor (T2), and a source of the second charging transistor (CT2) are coupled to a drain voltage V_{dd}.

6. The latch comparator of claim 5, wherein a drain of the first cross-coupled transistor (T1) and a drain of the fifth input transistor (T5) are electrically connected to the first node A, and a drain of the second cross-coupled transistor (T2) and a drain of the sixth input transistor (T6) are electrically connected to the second node A′.

7. The latch comparator of claim 6, wherein a source of the fifth input transistor (T5) is electrically connected to a drain of the third cross-coupled transistor (T3) and a source of the sixth input transistor (T6) is electrically connected to a drain of the fourth cross-coupled transistor (T4).

8. The latch comparator of claim 7, wherein a source of the third cross-coupled transistor (T3) and a source of fourth cross-coupled transistor (T4) are directly connected to a drain of the tail current transistor (T7), and a source of the tail current transistor (T7) is connected to ground.

9. The latch comparator of claim 8, wherein a gate of the first charging transistor (CT1), a gate of the second charging transistor (CT2) and a gate of the tail current transistor (T7) are connected to a same clock signal.

10. A method for driving a StrongARM latch comparator, the method comprising:
applying a voltage V_{DD} to the sources of the first and second PMOS cross-coupled transistors (T1, T2);
applying a ground voltage V₀ to a tail current transistor (T7), wherein third and fourth NMOS cross-coupled transistors (T3, T4) are connected to the tail current transistor, and wherein the first PMOS cross-coupled transistor (T1) has a gate electrically coupled to a gate of the third NMOS cross-coupled transistor (T3) and the second PMOS cross-coupled transistor (T2) has a gate electrically coupled to a gate of the fourth NMOS cross-coupled transistor (T4); and
applying a common mode voltage to a fifth input transistor (T5) and applying the common mode voltage and a small differential voltage to a sixth input transistor (T6),
wherein the fifth input transistor (T5) is electrically connected between the first PMOS cross-coupled transistor (T1) and the third NMOS cross-coupled transistor (T3), and the sixth input transistor (T6) is electrically connected between the second PMOS cross-coupled transistor (T2) and the fourth NMOS cross-coupled transistor (T4).

11. The method of claim 10, wherein
a first charging transistor (CT1) is connected to the first cross-coupled transistor (T1) so that their sources are connected to each other and their drains are connected to each other; and
a second charging transistor (CT2) is connected to the second cross-coupled transistor (T2) so that their sources are connected to each other and their drains are connected to each other.

12. The method of claim 11, wherein a drain of the tail current transistor (T7) is connected to a source of each of the third and fourth cross-coupled transistors (T3, T4).

13. The method of claim 12, further comprising:
outputting a first output voltage VAₙ from a first inverter (I1) connected to a first node A; and
outputting a second output voltage VAₙ from a second inverter (I2) connected to a second node A′.

14. The method of claim 13, further comprising:
applying a voltage V_{DD} to a source of the first cross-coupled transistor (T1), a source of the first charging transistor (CT1), a source of the second cross-coupled transistor (T2), and a source of the second charging transistor (CT2).

15. The method of claim 14, wherein a drain of the first cross-coupled transistor (T1) and a drain of the fifth input transistor (T5) are electrically connected to the first node A, and a drain of the second cross-coupled transistor (T2) and a drain of the sixth input transistor (T6) are electrically connected to the second node A′.

16. The method of claim 15, wherein a source of the fifth input transistor (T5) is electrically connected to a drain of the third cross-coupled transistor (T3) and a source of the sixth input transistor (T6) is electrically connected to a drain of the fourth cross-coupled transistor (T4).

17. The method of claim 16, wherein a source of the third cross-coupled transistor (T3) and a source of fourth cross-coupled transistor (T4) are directly connected to a drain of the tail current transistor (T7), and a source of the tail current transistor (T7) is connected to the ground.

18. The method of claim 11, further comprising:
applying a clock signal to a gate of the first charging transistor (CT1), a gate of the second charging transistor (CT2) and a gate of the tail current transistor (T7).

19. A circuit comprising:
first to fourth cross-coupled transistors (T1, T2, T3, T4), wherein the first cross-coupled transistor (T1) has a gate electrically coupled to a gate of the third cross-coupled transistor (T3) and the second cross-coupled transistor (T2) has a gate electrically coupled to a gate of the fourth cross-coupled transistor (T4); and
fifth and sixth input transistors (T5, T6),
wherein the fifth input transistor (T5) is directly, electrically, connected to the first cross-coupled transistor (T1) and to the third cross-coupled transistor (T3) and the sixth input transistor (T6) is directly, electrically, connected to the second cross-coupled transistor (T2) and the fourth cross-coupled transistor (T4).

20. The circuit of claim 19, further comprising:
a first charging transistor (CT1) connected to the first cross-coupled transistor (T1) so that their sources are connected to each other and their drains are connected to each other;
a second charging transistor (CT2) connected to the second cross-coupled transistor (T2) so that their sources are connected to each other and their drains are connected to each other;
a tail current transistor (T7) connected to the third and fourth cross-coupled transistors (T3, T4);
a first inverter (I1) connected to a first node A; and
a second inverter (I2) connected to a second node A′.
